(19) United States
(12) Patent Application Publication
(10) Pub. No.: US 2026/0269819 A1
(43) Pub. Date: Sep. 10, 2026

(54) SEMICONDUCTOR DEVICE AND PROTECTION SYSTEM

(71) Applicant: Mitsubishi Electric Corporation, Tokyo (JP)

(72) Inventor: Takeshi OMARU, Tokyo (JP)

(73) Assignee: Mitsubishi Electric Corporation, Tokyo (JP)

(21) Appl. No.: 18/873,242

(22) PCT Filed: Sep. 30, 2022
(86) PCT No.: PCT/JP2022/036644

§ 371 Date: Dec. 9, 2024

(51) Int. Cl. H03K 17/081

(52) U.S. Cl. CPC H03K 17/081

(57) ABSTRACT

It is an object to provide a technique enabling suppression of an abnormality caused by a short circuit current and a surge voltage of a power semiconductor switching element. A semiconductor device includes: a protection circuit to reduce a control voltage for the power semiconductor switching element based on a voltage at a first terminal of the power semiconductor switching element; a voltage divider resistor to generate a divided voltage based on a back electromotive force generated in an internal inductance; and a first semiconductor switching element to reduce the control voltage for the power semiconductor switching element at an earlier timing than the protection circuit and more sharply than the protection circuit based on the divided voltage.

### TECHNICAL FIELD

The present disclosure relates to semiconductor devices and protection systems.

### BACKGROUND ART

Various techniques have recently been proposed for semiconductor devices. For example, Patent Documents 1 and 2 propose a technique of reducing a gate voltage for a power semiconductor switching element when a short circuit in the power semiconductor switching element is detected to suppress a short circuit current and a surge voltage in the power semiconductor switching element.

### PRIOR ART DOCUMENTS

### Patent Documents

Patent Document 1: Japanese Patent Application Laid-Open No. 2007-228769

Patent Document 2: Japanese Patent Application Laid-Open No. 2001-008492

### SUMMARY

### Problem to be Solved by the Invention

In a conventional technique, a circuit to detect a short circuit is provided with a filter circuit for suppressing false detection of a short circuit, or a circuit to reduce a gate voltage for a power semiconductor switching element has a blanking function. This results in a relatively large delay in protection operation to reduce the gate voltage after the occurrence of a short circuit, leading to a problem in that a short circuit current and a surge voltage in the power semiconductor switching element cannot sufficiently be suppressed.

The present disclosure has been conceived in view of a problem as described above, and it is an object of the present disclosure to provide a technique enabling suppression of an abnormality caused by a short circuit current and a surge voltage in a power semiconductor switching element.

### Means to Solve the Problem

A semiconductor device according to the present disclosure includes: a power semiconductor switching element having a control terminal, a first terminal, and a second terminal, the first terminal and the second terminal being controlled by a control voltage applied to the control terminal; a protection circuit to reduce the control voltage for the power semiconductor switching element based on a voltage at the first terminal of the power semiconductor switching element; an internal inductance connected to the second terminal of the power semiconductor switching element; a voltage divider resistor to generate a divided voltage based on a back electromotive force generated in the internal inductance; and a first semiconductor switching element to reduce the control voltage for the power semiconductor switching element at an earlier timing than the protection circuit and more sharply than the protection circuit based on the divided voltage.

### Effects of the Invention

According to the present disclosure, the first semiconductor switching element reduces the control voltage for the power semiconductor switching element at an earlier timing than the protection circuit and more sharply than the protection circuit based on the divided voltage. According to such a configuration, an abnormality caused by a short circuit current and a surge voltage in the power semiconductor switching element can be suppressed.

These and other objects, features, aspects and advantages of the present disclosure will become more apparent from the following detailed description when taken in conjunction with the accompanying drawings.

### BRIEF DESCRIPTION OF DRAWINGS

FIG. 1 is a circuit diagram showing a configuration of a semiconductor device according to embodiment 1.

FIG. 2 is a diagram for describing a problem of a drive protection IC.

FIG. 3 is a diagram for describing operation of the semiconductor device according to Embodiment 1.

FIG. 4 is a diagram for describing operation of the semiconductor device according to Embodiment 1.

FIG. 5 is a circuit diagram showing a configuration of a semiconductor device according to Embodiment 2.

FIG. 6 is a circuit diagram showing a configuration of a semiconductor device according to Embodiment 3.

FIG. 7 is a circuit diagram showing a configuration of a semiconductor device according to Embodiment 4.

FIG. 8 is a circuit diagram showing a configuration of a semiconductor device according to Embodiment 5.

FIG. 9 is a circuit diagram showing a configuration of a semiconductor device according to Embodiment 6.

FIG. 10 is a circuit diagram showing a configuration of a semiconductor device according to Embodiment 7.

FIG. 11 is a circuit diagram showing a configuration of a semiconductor device according to Embodiment 8.

### DESCRIPTION OF EMBODIMENTS

Embodiments will be described below with reference to the accompanying drawings. Features described in the embodiments below are examples, and all the features are not necessarily required. In description made below, similar components in the embodiments bear the same or similar reference signs, and different components will mainly be described.

### Embodiment 1

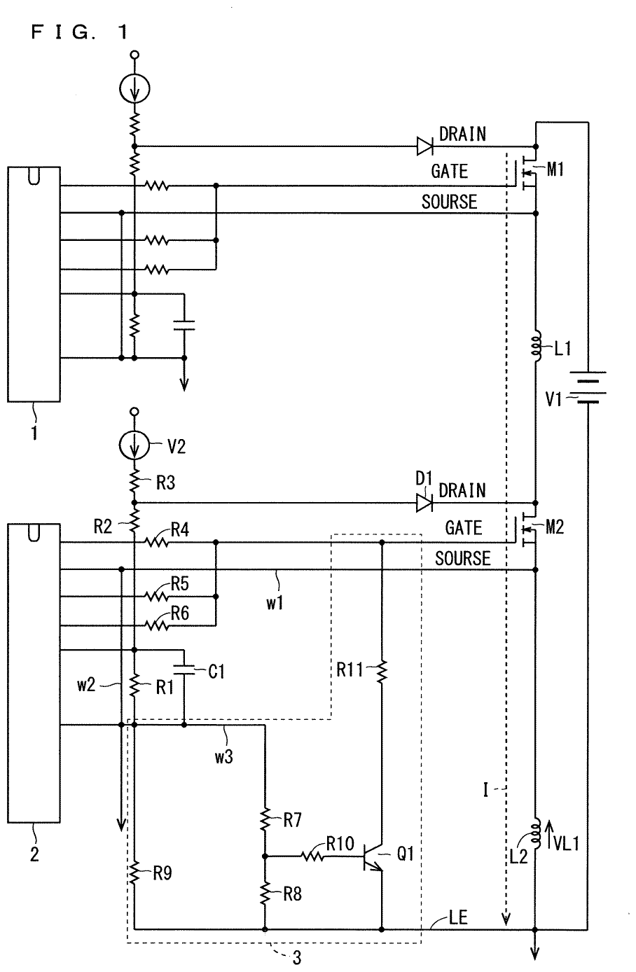

FIG. 1 is a circuit diagram showing a configuration of a semiconductor device according to Embodiment 1. The semiconductor device according to Embodiment 1includes drive protection integrated circuits (ICs) 1 and 2 as protection circuits, a realtime synchronous protection (RSP) circuit 3, power elements M1 and M2 as power semiconductor switching elements, internal inductances L1 and L2, and a power supply V1.

The power element M1 as an upper arm and the power element M2 as a lower arm are connected in series between opposite ends of the power supply V1. The power element M1 is similar to the power element M2, and the internal inductance L1 and the drive protection IC 1 connected to the power element M1 is similar to the internal inductance L2 and the drive protection IC 2 connected to the power element M2. Description will thus be made mainly on the power element M2, the internal inductance L2, and the drive protection IC 2 below.

The power element M2 has a control terminal and has a first terminal and a second terminal controlled by a control voltage applied to the control terminal. In an example of FIG. 1, the power element M2 is a metal oxide semiconductor field effect transistor (MOSFET), and the control terminal, the control voltage, the first terminal, and the second terminal are respectively a gate terminal, a gate voltage, a drain terminal, and a source terminal. The power element M2 is not limited to the MOSFET and may be an insulated gate bipolar transistor (IGBT), a reverse conducting-IGBT (RC-IGBT), and the like. The control terminal, the first terminal, and the second terminal may respectively be a base terminal, a collector terminal, and an emitter terminal.

A material for the power element M2 may be silicon (Si) or may be a wide bandgap semiconductor, such as silicon carbide (SiC), gallium nitride (GaN), and diamond. The power element M2 formed of the wide bandgap semiconductor enables stable operation at a high temperature and at a high voltage and a faster switching speed.

The internal inductance L2 is connected to the source terminal of the power element M2. The internal inductance L2 is a parasitic inductance of a bus bar of an unillustrated device package containing the power element M2, for example.

The drive protection IC 2 is connected to the drain terminal of the power element M2 via a high breakdown voltage diode D1 and a CR filter circuit. The CR filter circuit includes a resistor R1 and a capacitor C1 connected in parallel and a resistor R2 connected in series with them. A current source V2 is connected to a point of connection between the resistor R2 and the high breakdown voltage diode D1 via a resistor R3.

The drive protection IC 2 can detect a short circuit (hereinafter also referred to as a short circuit current) in the power element M2 based on a voltage at the drain terminal of the power element M2 connected via the high breakdown voltage diode D1 and the CR filter circuit. In Embodiment 1, the drive protection IC 2 determines that the short circuit (corresponding to a short circuit current I in FIG. 1) occurs in the power element M2 when a signal corresponding to the voltage at the drain terminal of the power element M2 exceeds a threshold. Such a scheme of detecting the short circuit in the power element M2 is generally referred to as a DESAT detection scheme.

The scheme of detecting the short circuit in the power element M2 is not limited to DESAT detection. For example, when the power element M2 has an unillustrated sense terminal, a current sensor scheme in which the drive protection IC 2 detects the short circuit in the power element M2 based on a current at the sense terminal may be used. For example, a scheme in which the drive protection IC 2 detects the short circuit in the power element M2 based on a voltage at a shunt resistor connected in series with the source terminal of the power element M2 may also be used.

The drive protection IC 2 selects any one of gate resistors R4, R5, and R6 or a combination of them based on whether the short circuit occurs in the power element M2 and is connected to the gate terminal of the power element M2 via the selected one or more gate resistors. For example, when determining that the short circuit occurs in the power element M2, the drive protection IC 2 reduces the gate voltage for the power element M2 to turn off the power element M2. It is preferable to reduce the gate voltage for the power element M2 as soon as possible from a viewpoint of suppressing the short circuit current, but, in this case, an excessive surge voltage exceeding a breakdown voltage of the power element M2 is generated in the power element M2.

The drive protection IC 2 is thus connected to the gate terminal of the power element M2 not via the gate resistors R4 and R5 used during normal operation in which the short circuit does not occur but via the gate resistor R6 having a higher resistance than the gate resistors R4 and R5 when determining that the short circuit occurs in the power element M2. The gate voltage for the power element M2 is thereby gradually reduced. According to the drive protection IC 2 having a soft shutdown mechanism to gradually reduce the gate voltage for the power element M2 as described above, generation of a surge voltage in the power element M2 during shutdown of the short circuit current can be suppressed. Short circuit protection only by the drive protection IC 2, however, can cause an excessive increase in short circuit current due to a protection delay, and, in such a case, it is difficult to suppress the surge voltage because a current to be shut down is excessive even when the soft shutdown mechanism works. Furthermore, suppression of the short circuit current and suppression of the surge voltage have sides having contradictory properties.

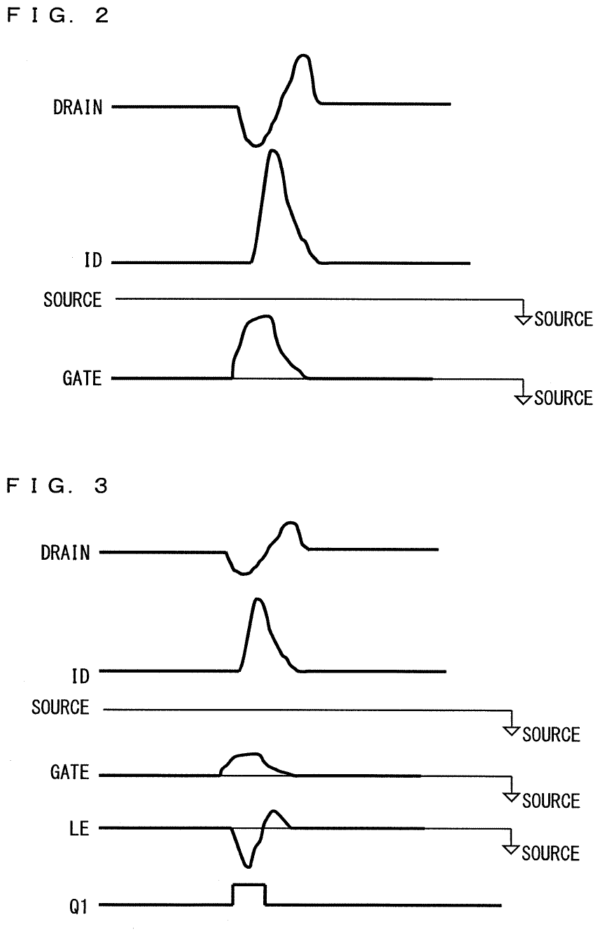

FIG. 2 is a diagram for describing a problem of the drive protection IC 2 and is specifically a diagram for describing operation when the short circuit occurs in the drive protection IC 2 alone not provided with the RSP circuit 3, which will be described below. FIG. 2 shows waveforms of a drain voltage (DRAIN), a drain current (ID), a source voltage (SOURCE), and the gate voltage (GATE). The drive protection IC 2 is provided with a CR filter circuit (herein a circuit including the resistors R1 and R2 and the capacitor C1) as described above not to falsely detect normal switching operation of the power element M2 as a short circuit. The drive protection IC 2 sometimes has a blanking function for suppression of false detection. Such a configuration, however, causes a relatively large delay between the occurrence of the short circuit and the time the drive protection IC 2 performs protection operation. Protection only by the drive protection IC 2 thus has not only a problem of the excessive increase in short circuit current in the power element M2 (see ID in FIG. 2) but also a problem in that the surge voltage (see DRAIN in FIG. 2) generated by the excessive increase in short circuit current cannot sufficiently be suppressed. That is to say, there is a problem in that a delay in suppression of the gate voltage when the short circuit occurs causes the excessive increase in short circuit current, and, due to the excessive increase in current, the surge voltage (see GATE in FIG. 2) cannot be suppressed even when the soft shutdown mechanism works. The semiconductor device according to Embodiment 1 includes, as a circuit to solve such a problem, the RSP circuit 3 (a circuit within a dashed line in FIG. 1) that operates coordinately and complementarily with the drive protection IC 2. Description will be made on the RSP circuit 3 below.

The RSP circuit 3 includes voltage divider resistors R7 and R8, a resistor R9 as a first resistor, a resistor R10 as a second resistor, a resistor R11 as a third resistor, and a first semiconductor switching element Q1. While the first semiconductor switching element Q1 is an NPN bipolar transistor in the example of FIG. 1, the first semiconductor switching element Q1 is not limited to the NPN bipolar transistor as described in another embodiment.

The voltage divider resistors R7 and R8 are connected in parallel with the internal inductance L2 via wires W1, W2, and W3 and a terminal LE in FIG. 1. The resistor R9 is connected in parallel with the internal inductance L2 as with the voltage divider resistors R7 and R8. The resistor R10 is connected between the voltage divider resistors R7 and R8 and a base terminal of the first semiconductor switching element Q1. The resistor R11 is connected between the gate terminal of the power element M2 and a collector terminal of the first semiconductor switching element Q1. An emitter terminal of the first semiconductor switching element Q1 is connected, via the terminal LE, to a second end of the internal inductance L2 as one end opposite the power element M2.

Herein, when a change in current (dI/dt) occurs in the internal inductance L2, a back electromotive force VL1 is generated in the internal inductance L2. When the back electromotive force VL1 is generated in the internal inductance L2, the voltage divider resistors R7 and R8 connected to the internal inductance L2 via the wires W1, W2, and W3 and the terminal LE in FIG. 1 generate a divided voltage based on the back electromotive force VL1 generated in the internal inductance L2.

The first semiconductor switching element Q1 reduces the gate voltage for the power element M2 based on the divided voltage generated by the voltage divider resistors R7 and R8. For example, when the divided voltage generated by the voltage divider resistors R7 and R8 exceeds a threshold voltage of the first semiconductor switching element Q1, the first semiconductor switching element Q1 is turned on to reduce the gate voltage for the power element M2.

A filter circuit and a blanking function are herein not provided between the base terminal of the first semiconductor switching element Q1 and the internal inductance L2. The first semiconductor switching element Q1 thus can reduce the gate voltage for the power element M2 at an earlier timing than the drive protection IC 2. The first semiconductor switching element Q1 can also reduce the gate voltage for the power element M2 more sharply than the drive protection IC 2 by adjusting a resistance of the resistor R11 and resistances of the gate resistors R4 to R6.

In a configuration as described above, when a short circuit current that is several times to ten or more times larger than a rated current of the power element M2 flows through the internal inductance L2, a large change in current (dI/dt) occurs and a large back electromotive force VL1 is generated in the internal inductance L2. In this case, the RSP circuit 3 is configured so that the divided voltage generated by the voltage divider resistors R7 and R8 based on the back electromotive force VL1 exceeds the threshold voltage of the first semiconductor switching element Q1. The RSP circuit 3 is configured to be able to distinguish between normal operation including the rated current and the occurrence of the short circuit depending on whether the large back electromotive force VL1 exceeds a threshold and reduces the gate voltage for the power element M2 at an earlier timing than the drive protection IC 2 and more sharply than the drive protection IC 2 only when the short circuit occurs.

FIG. 3 is a diagram for describing operation of the semiconductor device according to Embodiment 1 when the short circuit occurs. FIG. 3 shows a waveform of a voltage (LE) of the terminal LE and a waveform of on/off (Q1) of the first semiconductor switching element Q1 in addition to the waveforms shown in FIG. 2. The RSP circuit 3 reduces the gate voltage for the power element M2 at an earlier timing than the drive protection IC 2 and thus can suppress the short circuit current (see ID in FIG. 3) earlier than a configuration in which the RSP circuit 3 is not provided. The drive protection IC 2 then reduces the gate voltage for the power element M2 more gradually than the RSP circuit 3 using its own soft shutdown mechanism, so that generation of the surge voltage (see DRAIN in FIG. 3) in the power element M2 can be suppressed. Control of the gate voltage as described above can achieve both suppression of the short circuit current and suppression of the surge voltage (see GATE in FIG. 3).

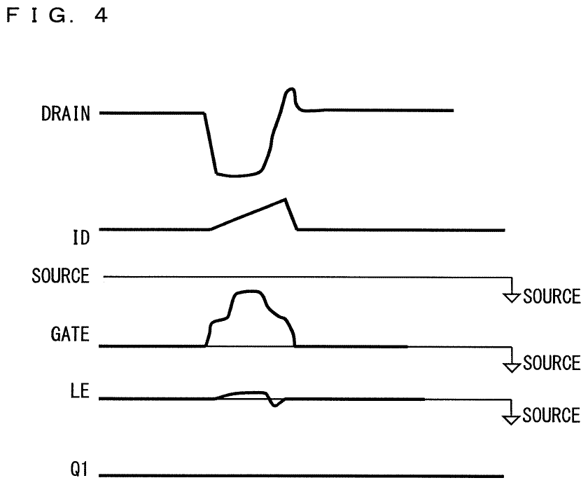

Resistances of the voltage divider resistors R7 and R8 and the resistor R10 are set appropriately in response to a value of the large back electromotive force VL1 generated when the short circuit occurs, so that turn-on of the first semiconductor switching element Q1 during normal operation of the power element M2 to reduce the gate voltage for the power element M2 can be suppressed. FIG. 4 shows operation of the semiconductor device according to Embodiment 1 during normal operation when the resistances of the voltage divider resistors R7 and R8 and the resistor R10 are set appropriately.

### Summary of Embodiment 1

According to the semiconductor device according to Embodiment 1 as described above, the first semiconductor switching element Q1 of the RSP circuit 3 distinguishes between normal operation and the occurrence of the short circuit depending on the value of the back electromotive force VL1 generated when the short circuit occurs based on the divided voltage generated by the voltage divider resistors R7 and R8 and, when the short circuit occurs, reduces the gate voltage for the power element M2 at an earlier timing than the drive protection IC 2 and more sharply than the drive protection IC 2 when the short circuit occurs. Such an effect can be produced while the influence exerted during normal operation is suppressed. According to such a configuration, an abnormality caused by the short circuit current and the surge voltage in the power element M2 when the short circuit occurs can be suppressed.

The RSP circuit 3 has negative feedback properties in which, as the short circuit current increases, the back electromotive force VL1 increases to enhance suppression of the short circuit current. The resistor R9 is connected in parallel with the internal inductance L2, so that negative feedback properties of a closed loop including a first end of the internal inductance L2 as one end on a side of the power element M2, the voltage divider resistors R7 and R8, the first semiconductor switching element Q1, the terminal LE, and the second end of the internal inductance L2 as one end opposite the power element M2 can be stabilized.

When the material for the power element M2 is the wide bandgap semiconductor, the power element M2 is often configured by a unipolar element, such as a MOSFET, to enable faster switching operation due to its operation properties. Faster switching operation, however, leads to an increase in short circuit current generated when the short circuit occurs in contradiction to an increase in power conversion efficiency due to reduction in switching loss. The power element M2 formed of the wide bandgap semiconductor enables stable operation at a high voltage, but the short circuit current generated when the short circuit occurs increases due to the high voltage in contradiction to an increase in power conversion efficiency due to reduction in amount of current with the use of the high voltage. Furthermore, when a gate structure of the power element M2 is a trench structure, an on resistance decreases to increase the power conversion efficiency, but, in contradiction to the increase in efficiency, a saturation current increases to increase the short circuit current generated when the short circuit occurs. To address this, the RSP circuit 3 uses the back electromotive force VL1 proportional to a value of the short circuit current. Thus, as the short circuit current increases, the back electromotive force VL1 increases, the first semiconductor switching element Q1 is deeply biased, and the gate voltage can sharply be reduced, so that the short circuit current can be suppressed in a negative feedback manner. The semiconductor device according to Embodiment 1 is thus particularly effective when the material for the power element M2 is the wide bandgap semiconductor.

### Modification

While the RSP circuit 3 is provided to the drive protection IC 2 in Embodiment 1, the RSP circuit 3 may not be provided to the drive protection IC 2. For example, the RSP circuit 3 may be provided to the drive protection IC 1 or may be provided to both the drive protection IC 1 and the drive protection IC 2.

### Embodiment 2

In the semiconductor device according to Embodiment 1, when the short circuit current is generated, the RSP circuit 3 reduces the gate voltage for the power element M2, so that the short circuit current can be suppressed. When the short circuit current is large, and a base current or a base voltage of the first semiconductor switching element Q1 is large, however, a time during which the first semiconductor switching element Q1 continues to be on, that is, a time during which the RSP circuit 3 continues to operate might be longer than assumed. As a result, when the RSP circuit 3 continues to operate after the drive protection IC 2 starts protection operation to reduce the gate voltage, the drive protection IC 2 might not be able to gradually reduce the gate voltage for the power element M2. In this case, an excessive surge voltage might be generated. To address this, a semiconductor device according to Embodiment 2 can solve such a problem as described below.

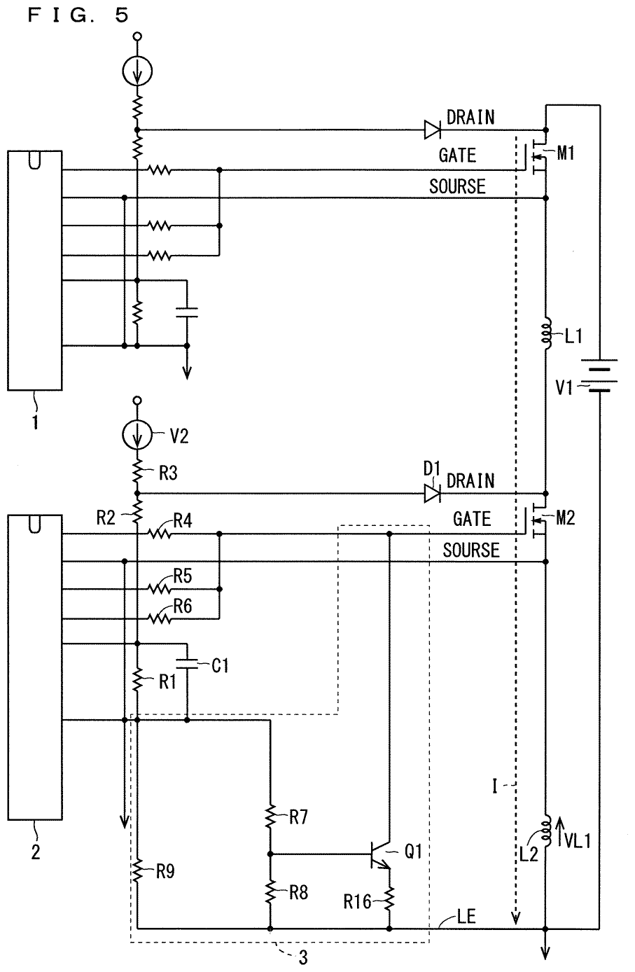

FIG. 5 is a circuit diagram showing a configuration of the semiconductor device according to Embodiment 2. The configuration in FIG. 5 is similar to the configuration in FIG. 1 from which the resistors R10 and R11 have been removed and to which a resistor R16 as a fourth resistor has been added. The resistor R16 is connected between the first semiconductor switching element Q1 and the second end of the internal inductance L2 as one end opposite the power element M2.

In the semiconductor device according to Embodiment 2 having such a configuration, an emitter follower circuit including the first semiconductor switching element Q1 is formed. According to such a configuration, the resistor R16 as a ground resistor of emitter follower has negative feedback properties, so that, after suppression of the short circuit current, the first semiconductor switching element Q1 can immediately be turned off to immediately stop operation of the RSP circuit 3. Operation of the RSP circuit 3 to reduce the gate voltage is immediately stopped after the drive protection IC 2 starts protection operation, thereby enabling a soft shutdown function for the gate voltage of the drive protection IC 2 to suppress the surge voltage. Continuation of operation of the RSP circuit 3 is thus suppressed, so that the short circuit current and the surge voltage of the power element M2 can more surely be suppressed.

### Embodiment 3

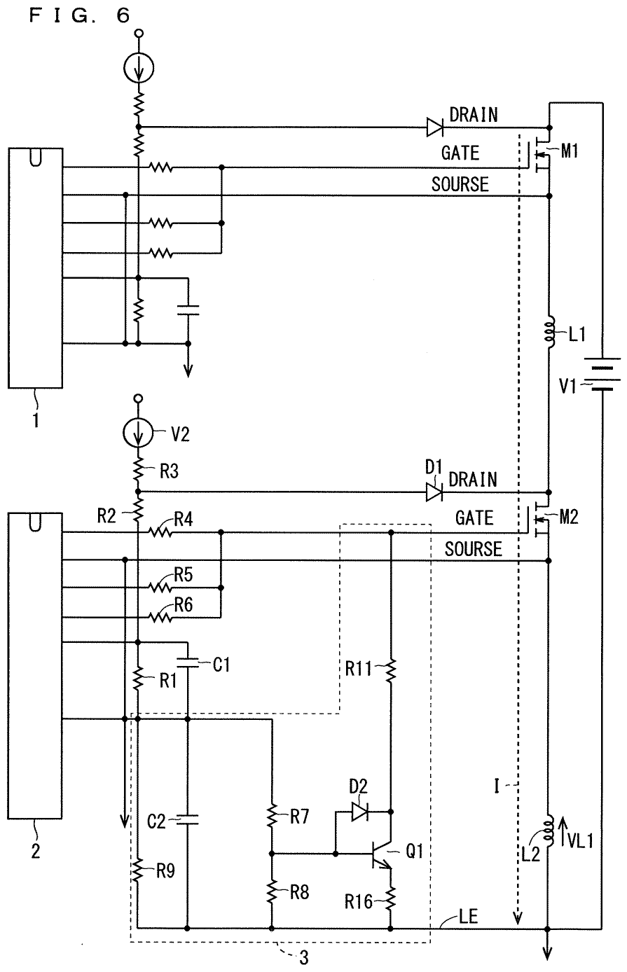

FIG. 6 is a circuit diagram showing a configuration of a semiconductor device according to Embodiment 3. The configuration in FIG. 6 is similar to the configuration in FIG. 5 to which a diode D2 as a first diode, the resistor R11 in FIG. 1, and a capacitor C2 as a first capacitor have been added.

The diode D2 is connected between the base terminal and the collector terminal of the first semiconductor switching element Q1 as the bipolar transistor. In an example of FIG. 6, an anode of the diode D2 is connected to the base terminal of the first semiconductor switching element Q1, and a cathode of the diode D2 is connected to the collector terminal of the first semiconductor switching element Q1. According to such a configuration, negative feedback is formed to divert part of a current on a side of the base terminal to a side of the collector terminal of the first semiconductor switching element Q1. The base current of the first semiconductor switching element Q1 can thereby be reduced early, so that a longer time during which the RSP circuit 3 continues to be on than assumed can be suppressed. As a result, continuation of operation of the RSP circuit 3 after the drive protection IC 2 starts protection operation is suppressed, thereby enabling the soft shutdown function for the gate voltage of the drive protection IC 2 to suppress the surge voltage. The short circuit current and the surge voltage of the power element M2 can thus more surely be suppressed than those in Embodiment 2.

The resistor R11 is connected between the gate terminal of the power element M2 and the collector terminal of the first semiconductor switching element Q1 as in Embodiment 1. According to such a configuration, the amount of suppression of the gate voltage for the power element M2 by the resistor R11 and the amount of base bias negative feedback by the resistor R16 can both be achieved. Control of an on time of the first semiconductor switching element Q1 and control of the gate voltage (i.e., a collector current amount) for the power element M2 can thus both be achieved.

The capacitor C2 is connected in parallel with the internal inductance L2 as with the resistor R9. According to such a configuration, an impedance of the RSP circuit 3 can be reduced, and the divided voltage based on the back electromotive force VL1 generated when the short circuit occurs can efficiently be applied to the base terminal of the first semiconductor switching element Q1. An excessive increase in back electromotive force VL1 can be suppressed, and a GND potential (reference potential) of the drive protection IC 2 can be stabilized, so that a failure of the circuit as a whole including the semiconductor device can be suppressed.

### Embodiment 4

In the semiconductor device described above, when the power element M2 turns off the short circuit current, a voltage VL2 in a direction opposite a voltage generated when the short circuit current is generated (i.e., when a current amount increases) is generated in the internal inductance L2 at the timing. The voltage VL2 is applied to the base terminal of the first semiconductor switching element Q1 in an opposite direction, so that, when the voltage VL2 exceeds a breakdown voltage of the base of the first semiconductor switching element Q1, a failure of the first semiconductor switching element Q1 can occur. Not only the failure of the first semiconductor switching element Q1 but also a failure of the drive protection IC 2 can occur. To address this, a semiconductor device according to Embodiment 4 can solve such a problem as described below.

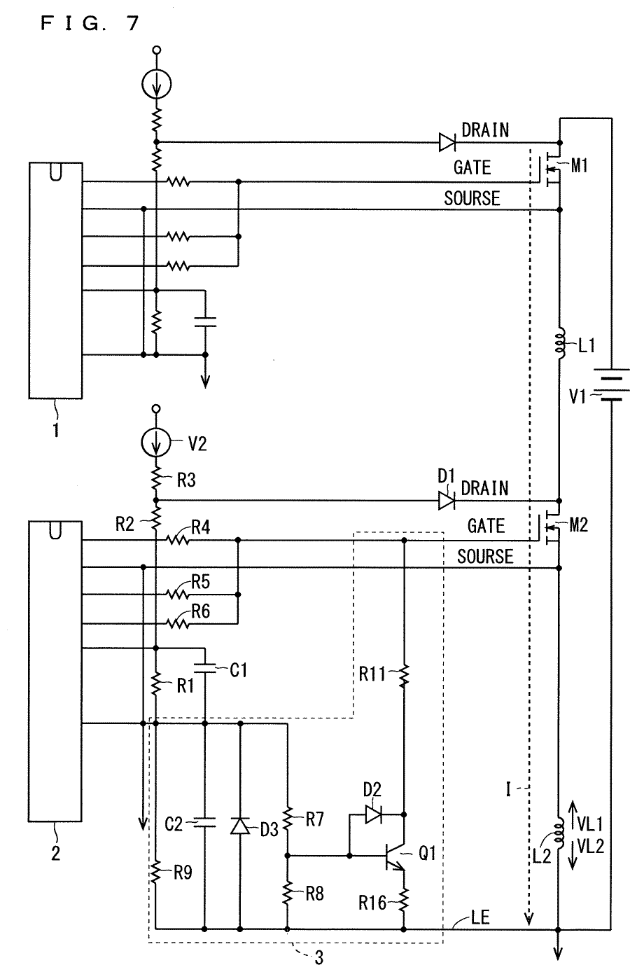

FIG. 7 is a circuit diagram showing a configuration of the semiconductor device according to Embodiment 4. The configuration in FIG. 7 is similar to the configuration in FIG. 6 to which a diode D3 as a second diode has been added.

The diode D3 is connected in parallel with the internal inductance L2 as with the resistor R9. In an example of FIG. 7, an anode of the diode D3 is electrically connected to the second end of the internal inductance L2, and a cathode of the diode D3 is electrically connected to the first end of the internal inductance L2. According to such a configuration, the diode D3 is turned on when the voltage VL2 is generated, so that the voltage applied to the base terminal of the first semiconductor switching element Q1 is clipped by a forward voltage. Failures of the first semiconductor switching element Q1 and the drive protection IC 2 caused by the voltage VL2 can thus be suppressed.

The diode D3 may be a Zener diode. In this case, a voltage applied to the voltage divider resistors R7 and R8 is clipped by a Zener voltage when the back electromotive force VL1 is generated, so that failures of the first semiconductor switching element Q1 and the drive protection IC 2 caused by the back electromotive force VL1 can be suppressed.

### Embodiment 5

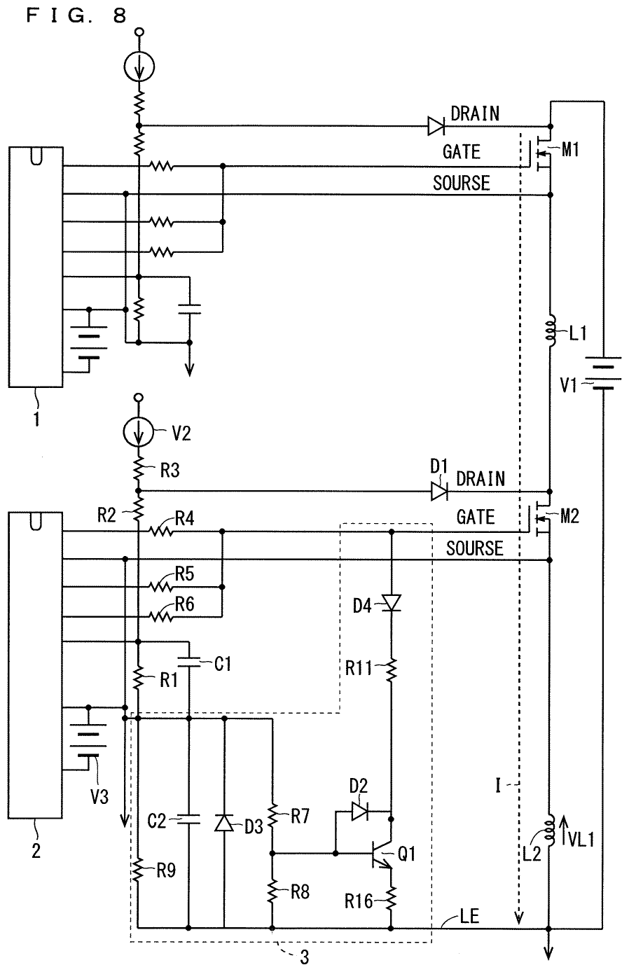

FIG. 8 is a circuit diagram showing a configuration of a semiconductor device according to Embodiment 5. The configuration in FIG. 8 is similar to the configuration in FIG. 7 in which a power supply V3 is connected to the drive protection IC 2 and the drive protection IC 2 can operate on both a positive power supply and a negative power supply and to which a diode D4 as a third diode has been added.

As shown in FIG. 8, in a configuration in which the drive protection IC 2 operates on both the positive power supply and the negative power supply, a shoot-through current sometimes flows from the power supply V3 used as the negative power supply to the first semiconductor switching element Q1. In this case, a current flows from the base terminal to the collector terminal of the first semiconductor switching element Q1, so that a failure of the first semiconductor switching element Q1 can occur. To address this, the semiconductor device according to Embodiment 5 can solve such a problem as described below.

The diode D4 is connected between the gate terminal of the power element M2 and the first semiconductor switching element Q1. In an example of FIG. 8, an anode of the diode D4 is connected to the gate terminal of the power element M2, and a cathode of the diode D4 is connected to the collector terminal of the first semiconductor switching element Q1 via the resistor R11. According to such a configuration, the diode D4 can suppress a flow of a current from the base terminal to the collector terminal of the first semiconductor switching element Q1, so that a failure of the first semiconductor switching element Q1 can be suppressed.

In a configuration in which the drive protection IC 2 operates both on the positive power supply and the negative power supply as in FIG. 8, a shoot-through current can flow from a GND potential (a midpoint potential) to a side of the negative power supply during a time during which the power element M2 is off to cause a load in the negative power supply. To address this, in Embodiment 5, the diode D4 is expected to suppress the load in the negative power supply, so that stabilization of operation of the RSP circuit 3 is expected.

### Embodiment 6

When a time from the occurrence of the short circuit to protection operation performed by the drive protection IC 2 is long in the semiconductor device described above, a time from completion of suppression of a peak short circuit current by the RSP circuit 3 to a start of protection operation performed by the drive protection IC 2 is sometimes long. As a result, the short circuit current can increase again within the time, and the short circuit current and the surge voltage of the power element M2 might not be able to appropriately be suppressed. To address this, a semiconductor device according to Embodiment 6 can solve such a problem as described below.

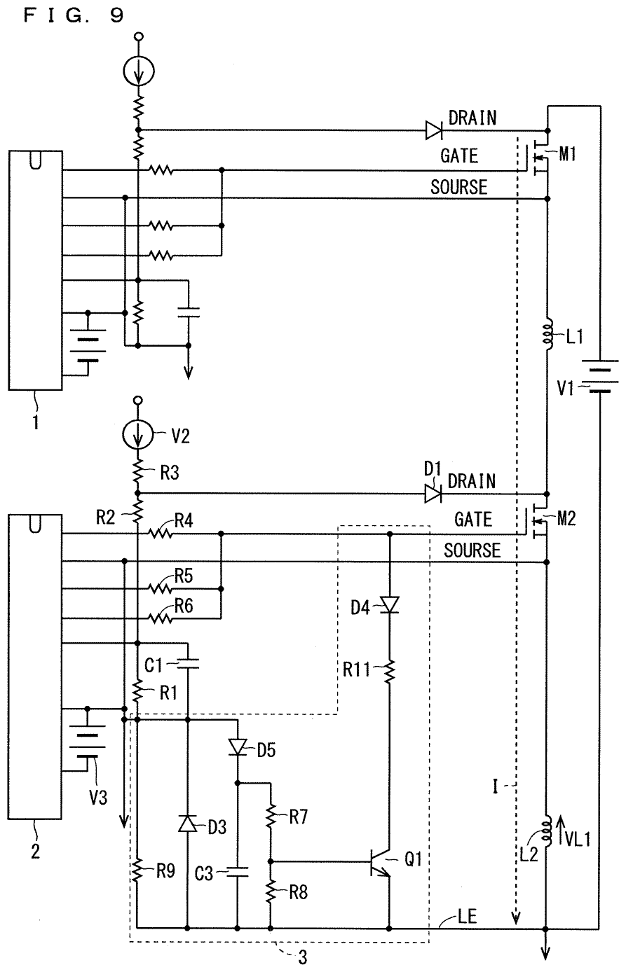

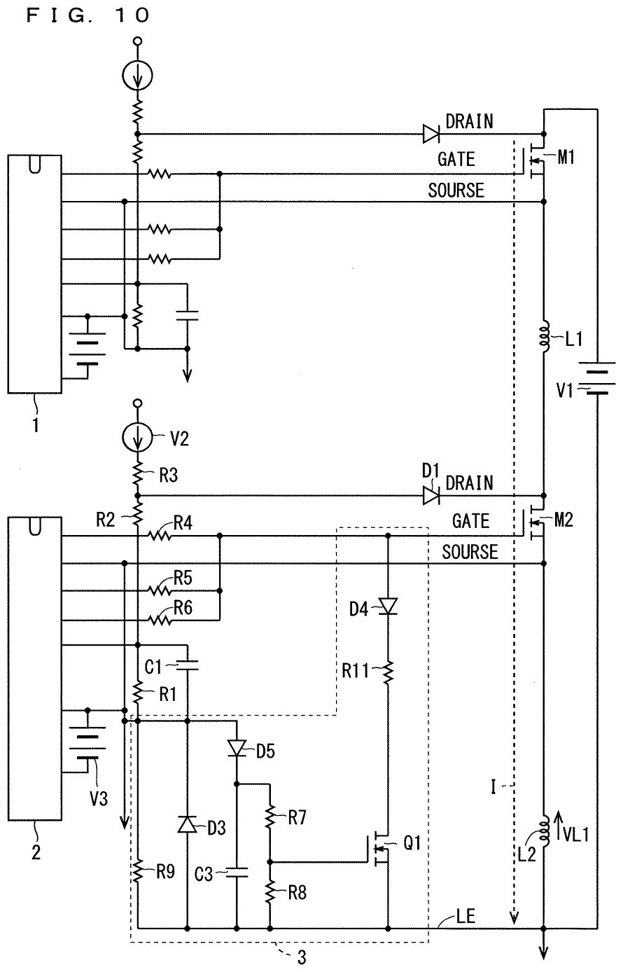

FIG. 9 is a circuit diagram showing a configuration of the semiconductor device according to Embodiment 6. The configuration in FIG. 9 is similar to the configuration in FIG. 8 from which the diode D2, the capacitor C2, and the resistor R16 have been removed and to which a capacitor C3 as a second capacitor and a diode D5 as a fourth diode have been added.

The capacitor C3 is connected in parallel with the voltage divider resistors R7 and R8. According to such a configuration, the capacitor C3 is charged by the back electromotive force VL1 generated when the short circuit occurs, so that the divided voltage of the voltage divider resistors R7 and R8, that is, the gate voltage for the first semiconductor switching element Q1 can be maintained for a certain time. The RSP circuit 3 can thus suppress the short circuit current for the certain time after generation of the short circuit current, so that the time from completion of suppression of the peak short circuit current by the RSP circuit 3 to the start of protection operation performed by the drive protection IC 2 can be reduced. As a result, the soft shutdown function for the gate voltage of the drive protection IC 2 is enabled to suppress the surge voltage. The short circuit current and the surge voltage of the power element M2 can thus appropriately be suppressed.

The diode D5 is connected in series with a parallel unit including the voltage divider resistors R7 and R8 and the capacitor C3. According to such a configuration, when the back electromotive force VL1 is relatively large, the back electromotive force VL1 is consumed for charging of the capacitor C3 via the diode D5, so that the back electromotive force VL1 can be mitigated to protect the semiconductor device.

### Embodiment 7

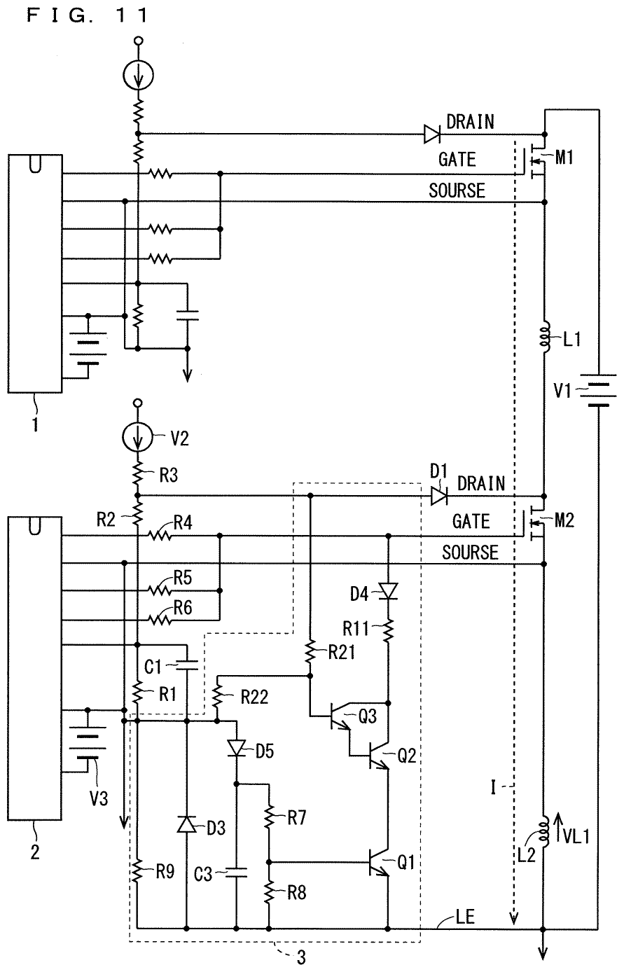

FIG. 10 is a circuit diagram showing a configuration of a semiconductor device according to Embodiment 7. The configuration in FIG. 10 is similar to the configuration in FIG. 9 in which the first semiconductor switching element Q1 has been changed from the bipolar transistor to a MOSFET. The MOSFET, which has a gate capacitance and is of a voltage driven type, is generally preferable to the bipolar transistor in adjusting the on time of the semiconductor switching element. Thus, according to the configuration according to Embodiment 7 in which the first semiconductor switching element Q1 is the MOSFET, coordination between the RSP circuit 3 and the drive protection IC 2 can be facilitated. That is to say, when the RSP circuit 3 suppresses the short circuit current, and the soft shutdown function for the gate voltage of the drive protection IC 2 is enabled, the RSP circuit 3 immediately stops, so that a configuration to achieve a series of operations to simultaneously suppress the surge voltage can be facilitated. The short circuit current and the surge voltage of the power element M2 can thus appropriately be suppressed.

### Embodiment 8

FIG. 11 is a circuit diagram showing a configuration of a semiconductor device according to Embodiment 8. The configuration in FIG. 11 is similar to the configuration in FIG. 9 to which a semiconductor switch unit has been added. The semiconductor switch unit includes a second semiconductor switching element Q2 and a third semiconductor switching element Q3 connected in Darlington configuration and resistors R21 and R22.

A collector terminal of the second semiconductor switching element Q2 is connected to the gate terminal of the power element M2 via the resistor R11 and the diode D4, and an emitter terminal of the second semiconductor switching element Q2 is connected to the collector terminal of the first semiconductor switching element Q1.

A collector terminal of the third semiconductor switching element Q3 is connected to the collector terminal of the second semiconductor switching element Q2, and an emitter terminal of the third semiconductor switching element Q3 is connected to a base terminal of the second semiconductor switching element Q2. A base terminal of the third semiconductor switching element Q3 is connected to the drain terminal of the power element M2 via the resistor R21 and the high breakdown voltage diode D1. One end of the resistor R22 is connected to a point of connection between the base terminal of the third semiconductor switching element Q3 and the resistor R21, and the other end of the resistor R22 is connected to the resistor R9, the diode D5, and the like.

The semiconductor switch unit having a configuration as described above connects the gate terminal of the power element M2 and the first semiconductor switching element Q1 based on a voltage at the drain terminal of the power element M2. For example, when the power element M2 is on during normal operation, the second semiconductor switching element Q2 of the semiconductor switch unit is maintained to be off not to connect the gate terminal of the power element M2 and the first semiconductor switching element Q1. On the other hand, when the power element M2 is off during normal operation or the short circuit occurs, the second semiconductor switching element Q2 of the semiconductor switch unit is turned on to connect the gate terminal of the power element M2 and the first semiconductor switching element Q1. Resistances of the resistors R21 and R22 are appropriately set so that the semiconductor switch unit performs such operation. Even if the second semiconductor switching element Q2 of the semiconductor switch unit is turned on when the power element M2 is off during normal operation, the first semiconductor switching element Q1 is not turned on unless the short circuit occurs, so that the RSP circuit 3 does not operate.

According to the semiconductor device according to Embodiment 8 as described above, the semiconductor switch unit can connect the gate terminal of the power element M2 and the first semiconductor switching element Q1 only when the short circuit occurs in the power element M2. Thus, even if the first semiconductor switching element Q1 is turned on during normal operation of the power element M2, the above-mentioned semiconductor switch unit can suppress the influence exerted by turn-on of the first semiconductor switching element Q1 on normal operation of the power element M2. That is to say, the RSP circuit 3 can operate only when the short circuit occurs. The semiconductor switch unit includes the second semiconductor switching element Q2 and the third semiconductor switching element Q3 connected in Darlington configuration, so that the semiconductor switch unit can detect the occurrence of the short circuit and operate even when a DESAT signal, that is, the voltage at the drain terminal of the power element M2 is small.

### Modifications

The function of each of the semiconductor devices described above may be achieved by a protection system to protect the semiconductor device via communication. For example, the semiconductor device may include the power element M2. The protection system may include a first protection circuit to reduce the gate voltage for the power element M2 based on the voltage at the drain terminal of the power element M2 and a second protection circuit to reduce the gate voltage for the power element M2 at an earlier timing than the first protection circuit and more sharply than the first protection circuit based on the back electromotive force VL1 generated in the internal inductance L2 connected to the source terminal of the power element M2. The first protection circuit corresponds to the drive protection IC 2, and the second protection circuit corresponds to the RSP circuit 3.

Embodiments and modifications can freely be combined with each other and can be modified or omitted as appropriate.

The foregoing description is in all aspects illustrative and not restrictive. It is understood that numerous unillustrated modifications can be devised.

### EXPLANATION OF REFERENCE SIGNS

2 drive protection IC, C2, C3 capacitor, D2, D3, D4, D5 diode, L2 internal inductance, M2 power element, Q1 first semiconductor switching element, Q2 second semiconductor switching element, Q3 third semiconductor switching element, R7, R8 voltage divider resistor, R9, R10, R11, R16 resistor, VL1 back electromotive force.

1. A semiconductor device comprising:
a power semiconductor switching element having a control terminal, a first terminal, and a second terminal, the first terminal and the second terminal being controlled by a control voltage applied to the control terminal;
a protection circuit to reduce the control voltage for the power semiconductor switching element based on a voltage at the first terminal of the power semiconductor switching element;
an internal inductance connected to the second terminal of the power semiconductor switching element;
a voltage divider resistor to generate a divided voltage based on a back electromotive force generated in the internal inductance; and
a first semiconductor switching element to reduce the control voltage for the power semiconductor switching element at an earlier timing than the protection circuit and more sharply than the protection circuit based on the divided voltage.

2. The semiconductor device according to claim 1, further comprising
a first resistor connected in parallel with the internal inductance.

3. The semiconductor device according to claim 1, further comprising:
a second resistor connected between the voltage divider resistor and the first semiconductor switching element; and
a third resistor connected between the control terminal of the power semiconductor switching element and the first semiconductor switching element.

4. The semiconductor device according to claim 1, further comprising
a fourth resistor connected between the first semiconductor switching element and one end of the internal inductance opposite the power semiconductor switching element.

5. The semiconductor device according to claim 4, wherein
the first semiconductor switching element is a bipolar transistor, and
the semiconductor device further comprises
a first diode connected between a base terminal and a collector terminal of the bipolar transistor.

6. The semiconductor device according to claim 4, further comprising
a first capacitor connected in parallel with the internal inductance.

7. The semiconductor device according to claim 6, further comprising
a second diode connected in parallel with the internal inductance.

8. The semiconductor device according to claim 7, further comprising
a third diode connected between the control terminal of the power semiconductor switching element and the first semiconductor switching element.

9. The semiconductor device according to claim 1, further comprising:
a second diode connected in parallel with the internal inductance;
a third diode connected between the control terminal of the power semiconductor switching element and the first semiconductor switching element;
a second capacitor connected in parallel with the voltage divider resistor; and
a fourth diode connected in series with a parallel circuitry including the voltage divider resistor and the second capacitor.

10. The semiconductor device according to claim 9, wherein
the first semiconductor switching element is a MOSFET.

11. The semiconductor device according to claim 9, further comprising
a semiconductor switch circuitry including a second semiconductor switching element and a third semiconductor switching element connected in Darlington configuration, wherein
the semiconductor switch circuitry connects the control terminal of the power semiconductor switching element and the first semiconductor switching element based on the voltage at the first terminal of the power semiconductor switching element.

12. A protection system for a semiconductor device, wherein
the semiconductor device comprises
a power semiconductor switching element having a control terminal, a first terminal, and a second terminal, the first terminal and the second terminal being controlled by a control voltage applied to the control terminal, and
the protection system comprises:
a first protection circuit to reduce the control voltage for the power semiconductor switching element based on a voltage at the first terminal of the power semiconductor switching element; and
a second protection circuit to reduce the control voltage for the power semiconductor switching element at an earlier timing than the first protection circuit and more sharply than the first protection circuit based on a back electromotive force generated in an internal inductance connected to the second terminal of the power semiconductor switching element.
